(19) United States
(12) Patent Application Publication
(10) Pub. No.: US 2007/0182433 A1
(43) Pub. Date: Aug. 9, 2007

(54) Wafer holder, and wafer prober and semiconductor manufacturing apparatus provided therewith

(75) Inventors: Masuhiro Natsuhara, Itami-shi (JP); Tomoyuki Awazu, Itami-shi (JP); Hirohiko Nakata, Itami-shi (JP); Katsuhiro Itakura, Itami-shi (JP)

Correspondence Address: GLOBAL IP COUNSELORS, LLP, 1233 20TH STREET, NW, SUITE 700, WASHINGTON, DC, 20036-2680, US

(73) Assignee: Sumitomo Electric Industries, Ltd., Osaka-shi (JP)

(21) Appl. No.: 11/699,043

(22) Filed: Jan. 29, 2007

(30) Foreign Application Priority Data
Feb. 6, 2006 (JP) 2006-028441

(51) Int. Cl. G01R 31/02

(52) U.S. Cl. 324/760

(57) ABSTRACT

A wafer holder that includes a cooling module for rapid cooling, that can further improve the heating uniformity of a wafer, and that can be appropriately used with a wafer prober, a coater/developer, or the like. The wafer holder includes a mounting stage arranged to mount a wafer on a mounting surface, a heat generator 1 arranged to heat the mounting stage, and a cooling module arranged to cool the mounting stage, wherein an outside diameter of the cooling module is smaller than an outside diameter of the mounting stage, and the heat generator 1 attached to the mounting stage is positioned further to the outside than the cooling module. Along with the heat generator 1, a supplementary heat generator may be positioned between the cooling module and the mounting stage or on a surface of the cooling module opposite the mounting stage.

### BACKGROUND OF THE INVENTION

1. Field of the Invention

The present invention relates to a wafer holder that can be appropriately used with a wafer prober for inspecting semiconductor wafers, a coater/developer for manufacturing semiconductor wafers, or other manufacturing apparatuses.

2. Description of the Background Art

In a semiconductor inspection step, a heating procedure is conventionally performed on a semiconductor substrate (wafer) to be treated. Specifically, the wafer is heated to a temperature higher than the normal operating temperature, potentially defective semiconductor chips are made to fail at an accelerated rate and removed, and a burn-in is performed to prevent the occurrence of defects after shipping. In the burn-in step, after the semiconductor circuits are formed on the semiconductor wafer and before the wafer is diced into individual chips, the electrical characteristics of each chip are measured while heating the wafer, and defective chips are removed.

In such a burn-in step, a holder is used to support the semiconductor substrate and heating the semiconductor substrate. Since the entire reverse surface of the wafer must be in contact with a ground electrode, conventional holders have been in the form of a flat metal plate. A wafer on which circuits are formed is mounted on the flat metal plate-form holder, and the electrical characteristics of the chips are measured.

A measuring device called a probe card, which is provided with numerous electrically conducting electrode pins, is pressed onto the wafer on the holder (wafer prober) with a force of tens to hundreds of kilograms-force when the electrical characteristics are measured. Therefore, if the holder is thin, the holder may be deformed by the pressing force, causing gaps to form between the wafer and the ground electrode, and contact failure to occur. Therefore, the use of thick metal plates having a thickness of 15 mm or greater has been necessary in order to preserve rigidity such that the holder is not deformed. The heat capacity of the holder therefore becomes relatively large, and long periods are required for raising and lowering the temperature, which has become a large obstacle to improving throughput.

Additionally, in the burn-in step, electricity is applied to the chips, and the electrical characteristics are measured, but with the increasing power output of chips in recent years, the chips generate large amounts of heat during the measuring of electrical characteristics, and are sometimes damaged by the heat they generate. Rapid cooling after measurement has therefore been needed. Additionally, the holder needs to be heated as uniformly as possible during measurement. Copper (Cu), which has a high thermal conductivity of 403 W/mK, has therefore generally been used as the metal that constitutes the holder.

Additionally, when the wafer is heated to a prescribed temperature; i.e., on the order of about 100° C. to about 200° C., the heat is conveyed to the holder drive system, and problems have arisen in regard to a loss of precision due to heat expansion of the metal components of the drive system. Further, due to the increased load during probing, the wafer holding prober must itself be rigid. Specifically, problems have been presented in that, if the wafer prober itself deforms under load during probing, the pins of the probe card will not be able to make uniform contact with the wafer, thereby rendering inspection impossible, or, in the worst case, damaging the wafer. Wafer probers should theoretically be made larger in order to inhibit deformation, but problems have arisen in that their weight increases, and the increased weight exerts an effect on the precision of the drive system.

Accordingly, in Japanese Laid-Open Patent Application Publication No. 2001-033484, a wafer prober is proposed wherein a thin metal layer and not a thick metal plate of copper or the like is formed on the surface of a thin but highly rigid ceramic substrate, resulting in minimized deformation and a low heat capacity. Since this wafer prober has high rigidity, contact failures do not occur. Since this wafer prober has low heat capacity, the temperature can be raised and lowered in a short time. Also disclosed is the use of an aluminum alloy, stainless steel or the like for the support platform used to position the wafer prober.

Such ceramic holders (wafer probers) do not deform because of their high rigidity, enabling satisfactory probing to be performed. However, the wafer mounting surface must be provided with a degree of flatness and parallelism at or below a constant value by precision working, for example. Moreover, the formation of a channel, hole, or the like for use in vacuum suction is necessary for mounting and adsorbing the wafer. Executing these procedures on high-rigidity materials has entailed high costs and resulted in other problems.

The wafer is heated to a prescribed temperature, i.e., about 100° C. to about 200° C., when inspected, and must be uniformly heated during this time. Although ceramic holders of the above description have relatively favorable heating uniformity on the wafer-mounting surface, further improvements in the heating uniformity have been desired. Furthermore, the wafer must be inspected in low-temperature regions at or below normal temperatures, as well as at high temperatures such as described above.

The present inventors have also proposed a mounting stage provided with a cooling module for rapidly cooling the wafer-mounting stage (Japanese Laid-Open Patent Application Publication No. 2004-014655). This wafer mounting stage has the advantage of being able to improve throughput when a resist or other resin applied to a wafer by a coater/developer or the like is subjected to a heat treatment. Although the heating uniformity of wafer-mounting stages provided with a cooling module is relatively good, further improvement is necessary. Furthermore, it has been necessary for the mounting stage to be cooled rapidly when inspections are performed in low-temperature regions.

### SUMMARY OF THE INVENTION

The present invention was devised in view of the above problems with the prior art. It is an object of the present invention to provide a wafer holder that can be appropriately used with a wafer prober to which a cooling module is provided for rapid cooling and with which the heating uniformity of a wafer can be further improved, and that can also be used with a coater/developer or other manufacturing apparatus for manufacturing a semiconductor wafer.

The wafer holder provided by the present invention comprises a mounting stage for mounting a wafer on a mounting surface, a heat generator for heating the mounting stage, and a cooling module for cooling the mounting stage, wherein an outside diameter of the cooling module is smaller than an outside diameter of the mounting stage, and the heat generator attached to the mounting stage is positioned further to the outside than the cooling module.

The wafer holder according to the present invention may have a supplementary heat generator positioned within the mounting stage, or a supplementary heat generator also positioned on a surface of the cooling module opposite the mounting stage in addition to the aforementioned heat generator.

In the wafer holder according to the present invention, the cooling module is fixed to the mounting stage or is made movable. Further, the wafer holder according to the present invention may comprise a support for supporting the mounting stage.

The present invention additionally provides an apparatus for manufacturing a semiconductor comprising the wafer holder according to the present invention, and further provides a wafer prober comprising the wafer holder according to the present invention.

According to the present invention, there can be provided a wafer holder that is capable not only of being rapidly cooled by a cooling module, but also of further improving the heating uniformity of a wafer. Therefore, the wafer holder of the present invention can be appropriately used with a wafer prober for inspecting a semiconductor wafer, a coater/developer for manufacturing a semiconductor wafer, or another manufacturing apparatus.

### BRIEF DESCRIPTION OF THE DRAWINGS

FIG. 1 is a cross-sectional view of an embodiment of a wafer holder of the present invention;

FIG. 2 is a cross-sectional view of another embodiment of a wafer holder of the present invention;

FIG. 3 is a cross-sectional view of another embodiment of a wafer holder of the present invention;

FIG. 4 is a cross-sectional view of another embodiment of a wafer holder of the present invention;

FIG. 5 is a plan view of the heat generator used in the working examples; and

FIG. 6 is a cross-sectional view of the support used in the working examples.

### DETAILED DESCRIPTION OF THE INVENTION

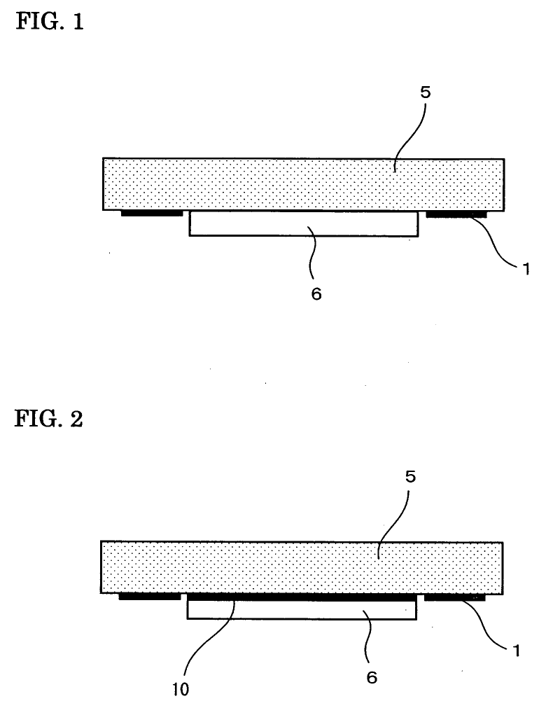

The wafer holder shown in FIG. 1 of the present invention is provided with a mounting stage 5 for mounting a wafer on a mounting surface, and a heat generator 1 for heating the mounting stage; and has a cooling module 6 with a smaller outside diameter than that of the mounting stage for mounting the wafer. The cooling module is fixed to the mounting stage or is at least made to come into contact with the mounting stage during cooling. In this case, the heat generator attached to the mounting stage is positioned further to the outside than the cooling module.

To uniformly heat the wafer-mounting stage, the heat generator is usually embedded in a relatively uniform manner within the mounting stage, or formed uniformly with the surface opposite the wafer-mounting surface, for example. Heat generated by the heat generator fully diffuses to the mounting stage, but problems have been presented in that the temperature inevitably decreases near the outer periphery of the mounting stage. Accordingly, in the wafer holder of the present invention, when a cooling module is present and has an outside diameter smaller than the outside diameter of the mounting stage, the heat generator is provided further to the outside than the cooling module. Moreover, the heat generator according to the present invention is embedded in a relatively uniform manner within the mounting stage, or formed uniformly with the surface opposite the wafer-mounting surface of the mounting stage, as above.

Heat thus generated from the heat generator provided to the outer side of the mounting stage also diffuses into the vicinity of the central area of the mounting stage, while also diffusing into the outer periphery of the mounting stage. Favorable heating uniformity can be ensured with this arrangement even though no heat generator is present near the central area. This is assumed to be due to the fact that since the vicinity of the central area is not directly heated, the heat flowing into the central area is low compared to the outer periphery, but since the amount of heat radiated in the central area is also lower than in the outer periphery, there is no longer any large difference in heat balance between the vicinity of the central area and the vicinity of the outer periphery, and favorable heating uniformity is obtained as a result. Additionally, having the heat generator present only on the outer side has advantages in that the structure can be made simpler than when the heat generator is present over the entire surface.

As described above, a heat generator is not present between the cooling module and the central area of the mounting stage, which offers the following advantages. Specifically, when a heat generator is formed on the central area of the surface opposite the wafer-mounting surface of the mounting stage, an insulation layer must be formed between the heat generator and the mounting stage or cooling module if the cooling module or the mounting stage acts as a conductor. Insulators such as resins having low thermal conductivity, glass, ceramics, and the like are typically used in the insulation layer. Therefore, substantial heat resistance is present between the mounting stage and the cooling module, and the cooling speed is inevitably reduced when the mounting stage is cooled. Particularly when both the cooling module and the mounting stage act as conductors, the heat resistance thereof will inevitably become extremely large. However, according to the present invention, an insulation layer having substantial heat resistance need not be positioned between the mounting stage and the cooling module as above, and the mounting stage can therefore be cooled rapidly by the cooling module.

However, a relatively soft material can be inserted between the mounting stage and the cooling module in order for the surfaces between the cooling module and the mounting stage to adhere tightly. However, in this case as well, it is not necessary to ensure insulation such as when a heat generator is present; therefore, the material may be relatively thin. Thus, aluminum, copper, other soft metals, the resin used to coat the heat generator, or another material may be selected to ensure tight adhesion. Additionally, the cooling module can be attached to the mounting stage by using screws, springs, or another mechanical implement; by brazing; or by another method, whereby the performance of the cooling module is adequately exhibited and the mounting stage can be cooled rapidly.

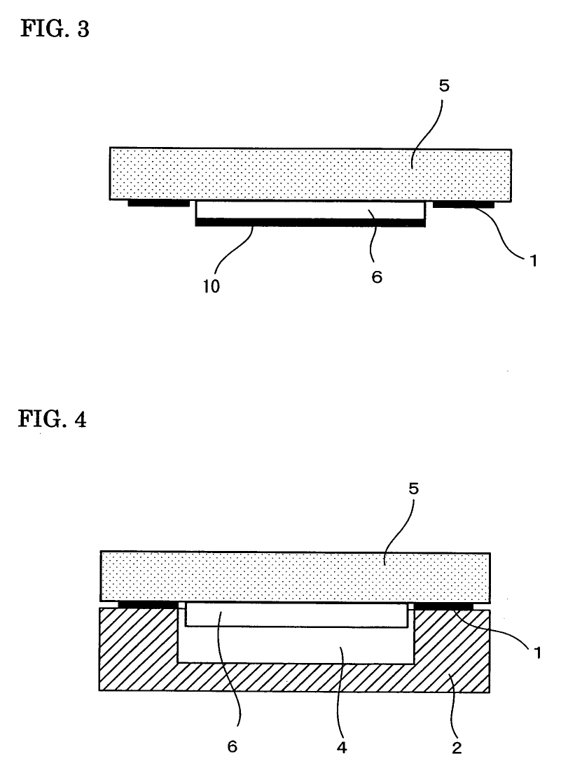

In addition to the heat generator positioned on the outer side of the cooling module as above, a heat generator 10 may be positioned as a supplementary device within the mounting stage as shown in FIG. 2 or on the surface of the cooling module opposite the mounting stage as shown in FIG. 3. Such a structure allows the heating temperature of the mounting stage to be rapidly raised. Particularly when a supplementary heat generator is provided to the surface of the cooling module on the side of the mounting stage or to the surface of the cooling module opposite the mounting surface, the supplementary heat generators in these locations are preferably controlled independently from the heat generator on the outer side of the cooling module.

After the temperature of the wafer holder has been adequately raised, however, the supplementary heat generators, which are provided within the mounting stage or on the surface of the cooling module opposite the mounting surface, raise the temperature near the central area and become a primary factor in disturbing the heating uniformity. Therefore, by controlling the supplementary heat generators independently from the outer heat generator, electrical current will be passed through the supplementary heat generators when the temperature is raised, and the speed with which the temperature of the mounting stage increases will increase. Reducing or stopping the output of the supplementary heat generators after or shortly before the end of the temperature increase will allow the wafer holder to have exceptional heating uniformity.

The thermal conductivity of the mounting stage on which the wafer is mounted is preferably 15 W/mK or greater. A thermal conductivity of less than 15 W/mK is not preferable because the temperature distribution of the wafer mounted on the mounting stage declines. If the thermal conductivity of the mounting stage is 15 W/mK or greater, the resulting heating uniformity poses no hindrance to probing. 99.5% pure alumina (30 W/mK thermal conductivity) is an example of a material with such thermal conductivity. It is especially preferable for the mounting stage to have a thermal conductivity of 170 W/mK or greater. Aluminum nitride (170 W/mK), Si—SiC complexes (170 to 220 W/mK) and the like are materials having such thermal conductivity. A mounting stage having this degree of thermal conductivity can have exceptional heating uniformity.

Ceramics, metal-ceramic complexes, and the like are also preferably used as the material constituting the mounting stage. Any Al—SiC complex made from aluminum and silicon carbide, or any Si—SiC complex made from silicon and silicon carbide that has relatively high thermal conductivity and allows heating uniformity to be readily achieved when the wafer is heated is preferably used as a metal-ceramic complex. Of these materials, Si—SiC complexes have an especially high Young's modulus and high thermal conductivity, and are therefore especially preferable. Copper, aluminum, nickel, stainless steel, and other metals can also be used for the mounting stage.

If a heat generator is not formed on the inner periphery of the wafer holder of the present invention where the cooling module is located, a material with an especially high thermal conductivity must be used for the mounting stage. In particular, the heating uniformity in such instances can be raised if the thermal conductivity is 100 W/mK or greater, which is therefore preferable.

Additionally, when the mounting stage is used to support the wafer in a wafer-prober capacity, a layer of metal must be formed at least on the wafer-mounting surface. There are no particular limitations as to the method for forming the metal layer, but nickel, gold, or another metal is preferably plated, vapor deposited, sputtered, or otherwise applied.

There are no particular limitations to the method for mounting the wafer on the mounting surface, but for wafer prober applications, concentric grooves are generally formed on the mounting stage and the grooves are used to create vacuum suction. Additionally, with coater/developers and the like, proximity methods are frequently used.

The heat generator used in the present invention is sandwiched by mica or another insulator, which has a simple structure and is therefore preferred. Nickel, stainless steel, silver, tungsten, molybdenum, chromium, metal alloys thereof, and other metallic materials can be used as the heat generator. Of these metals, stainless steel and Nichrome™ are preferable. Stainless steel, Nichrome™, and the like can be used to form the circuit pattern of the heat generator with relatively good precision by etching or other methods during the process of shaping the heat generator. These materials are also resistant to oxidation and relatively inexpensive, making them preferable in terms of withstanding usage for long periods of time even at high operating temperatures. A metal foil is an example of a specific configuration for the heat generator sandwiched by an insulator.

As long as the insulator that sandwiches the heat generator is heat-resistant, the composition thereof is not particularly restricted. For example, silicon resins, epoxy resins, phenol resins, and the like may be used in addition to mica, which was mentioned above. When the heat generator is sandwiched by such an insulating resin, a filler can be dispersed through the resin so that heat generated by the heat generator will be more smoothly conveyed to the mounting stage. The filler dispersed in the resin acts to increase the thermal conduction of the resin. The composition of the filler is not particularly restricted as long as the material does not react with the resin. Examples include boron nitride, aluminum nitride, alumina, and silica. The heat generator sandwiched by the insulator is screwed or otherwise mechanically fixed to the loading part of the mounting stage.

The heat generator can also be formed on the mounting stage, cooling module, or other component by screen printing or another method. If the mounting stage, cooling module, or other component is not an insulator, an insulation layer of glass or the like may be formed on the surface for forming the heat generator, whereupon the heat generator may be formed on the insulating surface. In such instances, there are no particular limitations as to the material used for the heat generator; example include silver, platinum, palladium, tungsten, molybdenum, other high-melting metals, and alloys and mixtures thereof

There are no particular limitations as to the material used for the cooling module, but aluminum, copper, and other metals, as well as alloys thereof are preferred for their relatively high thermal conductivity and ability to rapidly rid the mounting stage of heat. Additionally, stainless steel, magnesium alloys, nickel, or other metals may also be used. An oxidation-resistant metallic film made of nickel, gold, silver, or the like may be plated, sprayed, or otherwise formed on a cooling module made of the aforementioned metals in order to impart oxidation resistance thereto.

A ceramic material can also be used for the cooling module. The material in this instance is not particularly restricted, but aluminum nitride, silicon carbide, and the like are preferred for their relatively high thermal conductivity, making these materials able to quickly rid the mounting stage of heat. Additionally, silicon nitride and aluminum oxynitride have high mechanical strength and excellent durability, and are therefore preferred. Further, alumina, cordierite, steatite, and other oxide ceramics are relatively inexpensive and therefore preferred. Since a variety of materials may be selected for the cooling module, as described above, the material may be selected according to application. Among these materials, nickel-plated aluminum and nickel-plated copper are especially preferred due to their exceptional resistance to oxidation, high thermal conductivity, and relatively low cost.

The cooling module may be movable or may be fixed to the surface of the mounting stage opposite the mounting surface (the reverse surface). The question of whether to have a fixed or a movable cooling module can be decided according to the intended use. A movable case is preferable in that the rate of temperature increase as well as the rate of cooling can be increased by bringing the cooling module into contact with the reverse surface of the mounting stage when cooling is performed, and by separating the cooling module from the mounting stage when increasing the temperature. There are no particular limitations as to the method of movement, but the cooling module may be driven by a pneumatic cylinder, a hydraulic device, or another actuator.

When the cooling module is fixed to the mounting stage, the rate at which the temperature is increased is lower than with a movable case. However, cooling can be performed at a higher rate than with a movable case. When the wafer holder is used at a temperature below normal temperature, the cooling module is preferably fixed to the mounting stage to allow more-effective cooling. There are no particular limitations as to the method for fixing the cooling module to the mounting stage, but screwing or another mechanical method, as well as brazing or another method can be used.

A coolant may also be circulated through the cooling module. The flowing coolant is able to rapidly eliminate heat transmitted to the cooling module from the heat generator, thereby allowing the rate at which the heat generator is cooled to be further increased. Coolant must be circulated in particular when the mounting stage is operated at a temperature lower than normal temperature. There are no particular limitations as to the coolant circulated within the cooling module, but water, Fluorinert™, and the like may be used. However, Fluorinert™ or the like is used if the mounting stage is to be cooled to 0° C. or less. Since a liquid coolant may leak from the apparatus, gases such as nitrogen, atmospheric gas, or the like may also be circulated as a coolant.

In an ideal example of a cooling module having a coolant flowing therein, two plates that have relatively high thermal conductivity and are made of aluminum, copper, or the like are prepared. A mechanical or other process is used to form a flow channel in one of the plates for use in circulating the coolant, with the entire surface being plated with nickel in order to improve resistance to corrosion, oxidation, and the like. The other plate is also plated with nickel, and then both aluminum plates are affixed to each other. An O-ring or the like is inserted into the circumference of the flow channel in order to prevent the coolant from leaking out. The two plates are screwed, welded, or otherwise affixed together to yield a cooling module. Alternatively, two plates that have high thermal conductivity and are made of copper (oxygen-free copper), aluminum, or the like, are prepared. A mechanical or other process is used to form a flow channel in one of the copper plates. This copper plate and the other copper plate are brazed together along with a stainless steel pipe that acts as an inlet and outlet for the coolant. After the joining process, the entire surface is plated with nickel in order to improve resistance to corrosion and oxidation.

Additionally, as a separate aspect, a cooling module can be obtained by attaching a coolant-conveying pipe to an aluminum, copper, or other metal cooling plate having high thermal conductivity. There are no particular limitations as to the method for attaching the pipe; examples include brazing, and screwing using metal bands. In addition, a groove having a shape similar to the cross-section of the pipe may be formed on the cooling plate, and the contact area can be increased by affixing the pipe within the groove, allowing further increases in cooling efficiency. Further, an intermediate layer of a resin, ceramic, or other thermally conductive material may also be inserted in order to improve the adhesion between the cooling pipe and the cooling plate.

The wafer holder of the present invention as described above has exceptional heating uniformity and an exceptional cooling rate, and is therefore preferably used with coater/developers and other apparatuses for manufacturing semiconductors. Additionally, the wafer holder according to the present invention has exceptional heating uniformity and cooling characteristics, and is therefore able to exhibit uniform heating performance when used as a wafer prober as well.

A support 2 for supporting the mounting stage 5 can be used with the wafer holder of the present invention as shown in FIG. 4. The presence of a support is particularly preferable when the wafer holder is used for a wafer prober. The support in this instance acts to prevent heat generated by the heat generator from being conveyed to the drive system, and to ensure positional accuracy. Therefore, the thermal conductivity of the support is preferably 40 W/mK or less. If the thermal conductivity of the support exceeds 40 W/mK, the heat of the mounting stage will be readily conveyed to the support and will affect the precision of the drive system, which is undesirable. Since high temperatures of 150° C. or greater have been required when probing has been performed over the past several years, the support preferably has a thermal conductivity of 10 W/mK or less, and ideally 5 W/mK or less. If the thermal conductivity is of such a level, the amount of heat transmitted from the support to the drive system will greatly decrease.

The Young's modulus of the support is preferably 200 GPa or greater, and more preferably 300 GPa or greater. If the Young's modulus of the support is less than 200 GPa, the support itself may become deformed, which is undesirable. If the material has a Young's modulus of 300 GPa or greater, deformation of the support can be greatly reduced, allowing the support to be made smaller and lighter, which is especially preferable.

Mullite, alumina, and complexes of mullite and alumina (mullite-alumina complexes) are used as support materials that fulfill such thermal conductivity and Young's modulus levels. Mullite is preferred for its low thermal conductivity and strong heat-insulating effect, and alumina is preferred for its high Young's modulus and rigidity. Mullite-alumina complexes have a thermal conductivity that is lower than that of alumina, and a Young's modulus that is higher than that of mullite, and are therefore preferable overall.

There is no particular limitation on the shape of the support as long as the structure supports the outer or inner periphery of the mounting stage and does not lead to warping thereof. If the wafer holder is used as a coater/developer or other apparatus for manufacturing semiconductors, there are no particular limitations on the support as indicated above; e.g., the wafer holder may be accommodated in a container made of a metal such as stainless steel or the like.

The support surface of the support for supporting the mounting stage preferably has a thermally insulating structure for preventing heat from entering the support from the mounting stage. In one such thermally insulating structure, a notched groove is formed in the support, thereby reducing the contact area between the mounting stage and the support. A thermally insulting structure can also be obtained by forming a notched groove in the mounting stage. In such instances, the mounting stage must have a Young's modulus of 200 GPa or greater. Specifically, pressure is applied to the mounting stage by the probe card in wafer prober applications; therefore, materials with a small Young's modulus will undergo dramatic deformation if a notch is present in the mounting stage, which may lead to damage of the wafer or the mounting stage itself as well as other problems.

However, if a notch is formed in the support, such problems do not occur, which is therefore preferable. The notch may assume the form of concentric or radial grooves, multiple protuberances, or another configuration without particular limitation. However, a symmetrical shape is necessary for whatever shape is used. If the shape is not symmetrical, the pressure applied to the mounting stage will be impossible to disperse uniformly, and the mounting stage will be subjected to deformation, damage, or other problems, which is undesirable.

A plurality of pillar members may be positioned between the mounting stage and the support as a different aspect of a thermally insulating structure that prevents heat from entering the support from the mounting stage. Boundary surfaces can be formed between the mounting stage and the pillar members as well as between the pillar members and the support in a thermally insulating structure having pillar members between the mounting stage and the support, in contrast to when the mounting stage and support are integrated. Therefore, the boundary surfaces become heat-resistant layers, and if the area of contact between the mounting stage and the pillar members and the area of contact between the support and the pillar members are identical, the heat-resistive layers can be increased two-fold, which allows heat produced in the mounting stage to be efficiently insulated.

Preferably, eight or more pillar members are evenly positioned in a concentric or similar arrangement. In particular, since wafers have increased in size from 8 to 12 inches over the past several years, a smaller number of pillar members will result in greater distances between the pillar members, which will be more likely to produce war page when the pins of the probe card are pressed onto the wafer mounted on the mounting stage. Additionally, the pillar members may assume the configuration of a cylinder, triangular prism, quadrangular prism, another polygonal prism, a pipe or the like without particular limitation. Regardless of the configuration, the insertion of pillar members in this manner allows heat from the mounting stage to be blocked from entering the support.

The pillar members used in the thermally insulating structure above preferably have a thermal conductivity of 30 W/mK or less. If the thermal conductivity is higher than 30 W/mK, the thermal insulation effect deteriorates, which is undesirable. Examples of materials that can be used for the pillar members include silicon nitride, mullite, mulite-alumina complexes, steatite, cordierite, stainless steel, glass (fiber), polyimide resins, epoxy resins, phenol resins, other heat-resistant resins, and complexes of any of the above.

The contacting parts of the support and the mounting stage, or the parts in which there is contact between the pillar members and the support and the mounting stage, preferably have a surface roughness Ra of 0.1 μm or greater. If the surface roughness Ra is less than 0.1 μm, the shared contact area will increase and gaps between the parts will become relatively small. As a result, the volume of transmitted heat will be larger than when the Ra is 0.1 μm or greater, which is undesirable. There is no particular upper limit in regard to the surface roughness, but if the surface roughness Ra is 5 μm or greater, surface processing will become more expensive. Grinding, sand blasting, and other treatments are preferably used to obtain a surface roughness Ra of 0.1 μm or greater. However, the appropriate grinding and blasting conditions must be used in order to restrict the Ra to 0.1 μm or greater.

### WORKING EXAMPLES

### Working Example 1

Oxygen-free copper was used to prepare a mounting stage having a diameter of 210 mm and a thickness of 10 mm. Concentric grooves were machined into the stage, and within the grooves were formed counter-sink holes reaching through to the center of thickness of the copper plate. Side-holes connecting the counter-sink holes were formed so that vacuum suction would be obtained by creating a vacuum therethrough. The entire surface was nickel plated and polished to a surface roughness Ra of 0.15 μm to form a wafer mounting surface.

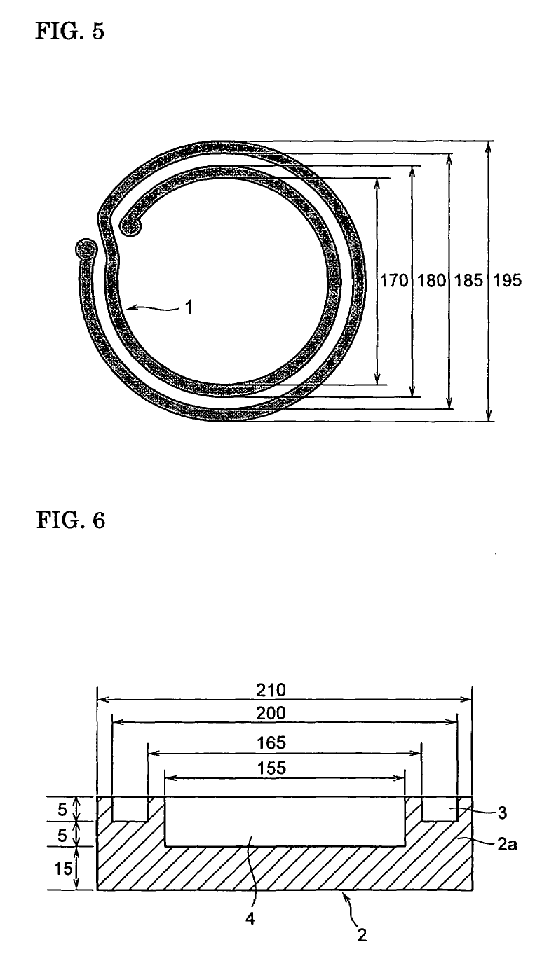

Next, a 50 μm-thick stainless steel foil was etched to form a heat generator 1 of the shape shown in FIG. 5, having an outside diameter of 195 mm and an inside diameter of 170 mm (full width: 25 mm). The heat generator 1 was sandwiched by a silicon resin in which BN powder had been dispersed, and screwed tightly to the reverse surface (opposite the mounting surface) of the mounting stage so that the centers of both components were aligned. Last, a power supply terminal was attached.

Meanwhile, two copper plates, each having a diameter of 150 mm and thicknesses of 4 mm and 1 mm, were prepared for use in a cooling module. A groove was machined to a depth of 3 mm and a width of 3 mm on the surface of the 4 mm-thick copper plate, which was soldered to the 1 mm-thick copper plate. The entire surface was then nickel-plated, resulting in a cooling module having a coolant flow channel. The cooling module was bolted securely in place to the reverse surface of the mounting stage so that the centers of both components were in alignment.

A mullite-alumina complex having a diameter of 210 mm and a thickness of 25 mm was prepared and machined into the shape shown in FIG. 6 to form a support. Specifically, the support 2 with a diameter of 210 mm had an outside annular convexity 2a with a width of 27.5 mm for supporting the outer periphery of the mounting stage. An annular groove 3 having a width of 17.5 mm and a depth of 5 mm was provided to an upper surface of the outside annular convexity 2a. A central concavity 4 with an inside diameter of 155 mm and a depth of 10 mm was formed in the center of the support 2.

The mounting stage in which the cooling module and heat generator 1 were fixed to the reverse surface opposite the wafer loading surface as described above was loaded onto the support 2, resulting in a wafer holder. The mounting stage in the wafer holder was supported by the outside annular convexity 2a of the support 2. The heat generator 1, which was fixed to the outer side of the reverse surface of the mounting stage, was housed within the annular groove 3 of the support 2, while the cooling module, which was fixed to the inner side of the reverse surface of the mounting stage, was housed within the central concavity 4 of the support 2.

A wafer temperature gauge having a diameter of 200 mm was loaded onto the wafer-mounting surface of the wafer holder, and measurements were made of the time for the temperature to be raised from normal temperature to 200° C. as well as the heating uniformity at 200° C. It required 15 minutes for the temperature to rise to 200° C., and the heating uniformity was 200±0.5° C.

Next, a pre-inspection wafer was loaded in place of the wafer temperature gauge. The temperature was raised to 150° C. and a probing test was performed. The heating uniformity was 150±0.3° C., with satisfactory probing having been carried out successfully. The wafer was cooled with air fed as a coolant into the cooling module of the wafer holder. The wafer took 8 minutes to cool from 150° C. to 70° C. Further, the temperature of the mounting stage was reduced from room temperature to −50° C. by circulating Fluoriner™ into the cooling module as a coolant, and a probing test was performed. The resulting cooling rate (cooling time) was 12 minutes, showing that a relatively high rate could be obtained. Normal probing was also successfully performed in low-temperature regions.

### Working Example 2

Two mounting stages were prepared with a cooling module in the central area of the reverse surface, and a heat generator fixed to the outer side of the reverse surface, as in Working Example 1. A supplementary heat generator etched from a Nichrome™ foil and sandwiched by a silicon resin in which BN powder had been dispersed was screwed tightly to the mounting stage. In the case of the mounting stages, the supplementary heat generator was positioned between the cooling module and the mounting stage, and in the other mounting stage the supplementary heat generator was positioned on the surface of the cooling module opposite the mounting stage. The outer heat generator and the supplementary heat generator were able to be controlled independently.

These mounting stages were loaded on supports as in Working Example 1. The temperature of the mounting surfaces was raised to 200° C., but the power fed to the supplementary heat generators was stopped when a temperature of 195° C. was reached. The results were as follows. The time for the temperature to rise to 200° C. was 10 minutes for the wafer holder with the supplementary heat generator between the cooling module and the mounting stage, and 12 minutes for the wafer holder with the supplementary heat generator on the surface of the cooling module opposite the wafer-mounting surface. The heating uniformity in both cases was 200±0.5° C., which was the same as in Working Example 1.

The time needed for the temperature to decrease from 150° C. to 70° C. was measured as in Working Example 1, with the cooling time being 10 minutes with the supplementary heat generator between the cooling module and the mounting stage, and 8 minutes with the supplementary heat generator on the surface of the cooling module opposite the wafer-mounting surface. The rate (cooling time) at which the temperature decreased from room temperature to −50° C. was 12 minutes with the supplementary heat generator on the side of the cooling module opposite the mounting surface, which was the same result as in Working Example 1, but was 30 minutes or more with the supplementary heat generator between the mounting stage and the cooling module. Normal probing was carried out successfully in both cases.

### Working Example 3

A movable system was adopted in the wafer holder of Working Example 1 whereby a movable cooling module was brought into contact with, or moved away from, the reverse surface of the mounting stage by control with an air cylinder. The wafer holder was tested as in Working Example 1, except that the cooling module was separated from the reverse surface of the mounting stage when the temperature was raised and brought into contact with the reverse surface of the mounting stage when cooling was performed. Twelve minutes was needed for the temperature to rise to 200° C., the heating uniformity was 200±0.4° C., and twelve minutes was also needed for the temperature to drop from 150° C. to 70° C. The rate (cooling time) at which the temperature decreased from room temperature to −50° C. was 17 minutes.

### Working Example 4

The wafer holder of Working Example 1 was housed within a stainless steel container having a diameter of 215 mm and a depth of 25 mm. However, in Working Example 4, vacuum suction grooves were not formed in the mounting stage. Counter-sink parts having a depth of 0.9 mm were formed evenly in ten locations on the mounting surface. Alumina balls having a diameter of 1 mm were placed therein to provide proximity. The heating uniformity measured at 200° C. using this wafer holder was 200±0.4° C., as in Working Example 1. The cooling rate and other characteristics were substantially the same as in Working Example 1. Satisfactory results could be obtained when a curing test was performed on a resin applied to a wafer using this wafer holder.

### COMPARATIVE EXAMPLE

A cooling module having a diameter of 180 mm was prepared and fixed to the reverse surface of a mounting stage that was similar to the one used in Working Example 1. A heat generator was positioned between the cooling module and the mounting stage by the same method used in Working Example 1. The mounting stage was loaded onto a support, resulting in a wafer holder. When the temperature of the wafer holder was raised to 200° C., the temperature on the outer edge of the mounting stage decreased sharply, resulting in a heating uniformity of 200±1.1° C. The rate (cooling time) at which the temperature decreased from room temperature to −40° C. was 20 minutes or more.

What is claimed is:

1. A wafer holder comprising:
a mounting stage including a mounting surface configured and arranged to receive a wafer thereon;
a cooling module configured and arranged to cool the mounting stage; and
a heat generator attached to the mounting stage, and configured and arranged to heat the mounting stage, the heat generator having an outside diameter that is larger than an outside diameter of the cooling module, the heat generator being positioned outwardly with respect to the cooling module.

2. The wafer holder according to claim 1, further comprising
a supplementary heat generator disposed inside of the mounting stage.

3. The wafer holder according to claim 1, further comprising
a supplementary heat generator positioned on a surface of the cooling module opposite the mounting stage.

4. The wafer holder according to claim 1, wherein
the cooling module is fixed to the mounting stage.

5. The wafer holder according to claim 1, wherein
the cooling module is movable with respect to the mounting stage.

6. The wafer holder according to claim 1, further comprising
a support member configured and arranged to support the mounting stage.

7. A semiconductor manufacturing apparatus comprising the wafer holder according claim 1.

8. A wafer prober comprising the wafer holder according to claim 1.
